(19) United States
(12) Patent Application Publication
(10) Pub. No.: US 2026/0114194 A1
(43) Pub. Date: Apr. 23, 2026

(54) METHOD FOR FORMING SILICON-CONTAINING FILM, AND COMPOSITION AND SILICON PRECURSOR COMPOUND USED THEREFOR

(71) Applicant: UP CHEMICAL CO., LTD., Pyeongtaek-si (KR)

(72) Inventors: Byung Kwan KIM, Pyeongtaek-si (KR); Jin Sik KIM, Pyeongtaek-si (KR); Da Som YU, Pyeongtaek-si (KR); Seung Gyun HONG, Pyeongtaek-si (KR)

(21) Appl. No.: 19/147,335

(22) PCT Filed: Jan. 12, 2024
(86) PCT No.: PCT/KR2024/000647

§ 371 Date: Jul. 11, 2025

(30) Foreign Application Priority Data
Jan. 13, 2023 (KR) 10-2023-0005282

(51) Int. Cl. H10P 14/60; C01B 33/12; C07F 7/10; C23C 16/40; C23C 16/455; H10P 14/692

(52) U.S. Cl. CPC H10P 14/6681; C01B 33/126; C07F 7/10; C23C 16/402; C23C 16/45553; H10P 14/6339; H10P 14/69215

(57) ABSTRACT

A composition for forming a silicon-containing film, the composition containing a silicon precursor compound represented by chemical formula 1, can be used to efficiently form a silicon-containing film, including a silicon-containing oxide film or a silicon-containing composite metal oxide film, at a high temperature of at least 600° C., wherein the silicon-containing film can be controlled to have a desired thickness and composition, and can be formed to have excellent coverage and uniformity even on a substrate having a complex shape.

### TECHNICAL FIELD

The present invention relates to a method for forming a silicon-containing film and a composition and a silicon precursor compound used therein. Specifically, the present invention relates to a method for forming a silicon-containing film using a composition for forming a silicon-containing film comprising a silicon precursor compound having a specific structure at a high temperature of 600° C. or higher, a silicon-containing film prepared thereby, and a composition and a silicon precursor compound used therein.

### BACKGROUND ART

A silicon-containing film is one of the thin films essential for driving non-semiconductor devices such as logic devices, as well as semiconductors such as DRAM, flash memory, resistive memory (ReRAM), or phase change memory (PCRAM).

As a silicon-containing film, a silicon-containing oxide film has a high deposition rate, whereas a silicon-containing nitride film has a slow deposition rate. For various applications, there is a demand for a silicon-containing film that can be selectively deposited only on a desired location.

In addition, as products having a complex shape such as a high aspect ratio and a three-dimensional structure are variously developed in the memory field and non-memory field, there is a demand for a composition for forming a silicon-containing film comprising a silicon precursor compound that can be used for atomic layer deposition (ALD), which is suitable for process temperatures for various application fields and can overcome a high step ratio.

In particular, it is important to exhibit self-limiting film growth characteristics in order to overcome the step ratio that may be caused by the high integration and scale down of the device.

Therefore, there is a demand for developing a composition for forming a film comprising a silicon precursor compound that has self-limiting film growth characteristics at a high temperature of 600° C. or higher, is suitable for ALD, is capable of forming a uniform and dense film, and has a characteristic resistant to stress; and a method for forming a silicon-containing film using the same.

### PRIOR ART DOCUMENTS

(Patent Document 1) Korean Patent No. 10-0734393

### DISCLOSURE OF INVENTION

### Technical Problem

A technical problem to be solved by the present invention is to provide a method for forming a silicon-containing film using a composition for forming a silicon-containing film comprising a silicon precursor compound having a specific structure at a high temperature of 600° C. or higher, and a silicon-containing film prepared thereby.

Another technical problem to be solved by the present invention is to provide a silicon precursor compound having a specific structure.

Another technical problem to be solved by the present invention is to provide a process for preparing the silicon precursor compound.

Another technical problem to be solved by the present invention is to provide a composition for forming a silicon-containing film comprising the silicon precursor compound.

However, the problems to be solved by the present invention are not limited to those mentioned above, and other problems not mentioned will be clearly understood by those skilled in the art from the following description.

### Solution to Problem

The present invention provides a method for forming a silicon-containing film that comprises depositing a silicon-containing film using a composition for forming a silicon-containing film comprising a silicon precursor compound represented by Formula 1:

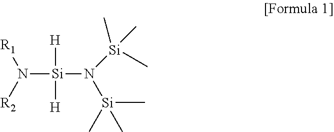

In Formula 1,
R₁ and R₂ are each independently selected from the group consisting of hydrogen and a linear or branched C₁-C₄ alkyl group, or
R₁ and R₂ are directly or indirectly connected to each other to form a substituted or unsubstituted C₄-C₉ cyclic group, wherein the C₄-C₉ cyclic group comprises one or two nitrogen (N) atoms and zero to two oxygen (O) atoms.

In addition, the present invention provides a composition for forming a silicon-containing film that comprises a silicon precursor compound represented by the above Formula 1 and used in the deposition of a silicon-containing film.

In addition, the present invention provides a use of the silicon precursor compound represented by the above Formula 1 for forming a silicone-containing film.

In addition, the present invention provides a silicon-containing film formed by the method for forming a silicon-containing film.

Further, the present invention provides a silicon precursor compound represented by Formula 0 or Formula 1:

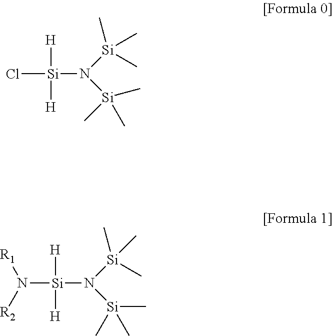

In Formula 1,
R₁ and R₂ are each independently selected from the group consisting of hydrogen and a linear or branched C₁-C₄ alkyl group, or
R₁ and R₂ are directly or indirectly connected to each other to form a substituted or unsubstituted C₄-C₉ cyclic group, wherein the C₄-C₉ cyclic group comprises one or two nitrogen (N) atoms and zero to two oxygen (O) atoms.

### Advantageous Effects of Invention

The method for forming a silicon-containing film according to an embodiment of the present invention can efficiently form a silicon-containing film comprising at least one selected from the group consisting of a silicon-containing oxide film and a silicon-containing composite metal oxide film using a composition for forming a silicon-containing film comprising a silicon precursor compound having a specific structure at a high temperature of 600° C. or higher. It is possible to precisely control the desired film thickness and composition and to form a uniform silicon-containing film with excellent coverage even on a substrate having a complex shape.

In particular, the method for forming a silicon-containing film of the present can be applied to various fields such as moisture penetration barriers of memory devices, logic devices, display devices, and organic light emitting diode (OLED) devices, and a film of a desired thickness can be obtained at a high temperature of 600° C. or higher during film deposition. Thus, it can be very effectively utilized in electronic devices that require excellent properties and coverage of a film.

### BRIEF DESCRIPTION OF DRAWINGS

FIG. 1 is a graph showing the deposition characteristics of a silicon-containing oxide film with respect to a temperature of 600° C. to 850° C. when the silicon-containing film is deposited using a composition for forming a silicon-containing film comprising each of the silicon precursor compounds of Examples 1 and 3 and Comparative Examples 1 and 2 of the present invention.

FIG. 2 is a graph showing the results of secondary ion mass spectrometry (SIMS) of a silicon-containing oxide film deposited at a temperature of 750° C. using a composition for forming a silicon-containing film comprising each of the silicon precursor compounds of Example 3 and Comparative Example 1 of the present invention.

FIG. 3 is a transmission electron microscope (TEM) image confirming the step coverage by deposition on a patterned wafer at 750° C. using a composition for forming a silicon-containing film comprising each of the silicon precursor compounds of Examples 1 and 3 and Comparative Example 1 of the present invention.

FIG. 4 is a transmission electron microscope (TEM) image confirming the step coverage by deposition on a patterned wafer at 650° C. using a composition for forming a silicon-containing film comprising each of the silicon precursor compounds of Example 3 and Comparative Example 1 of the present invention.

### BEST MODE FOR CARRYING OUT THE INVENTION

Hereinafter, the present application will be described in more detail.

The advantages and features of the present invention and the methods of achieving them will become apparent with reference to the embodiments described hereinafter. However, the present invention is not limited to the embodiments described below, but may be embodied in various different forms. These embodiments are provided so that the disclosure of the present invention will be thorough and complete, and will fully convey the scope of the invention to those skilled in the art. The invention is defined by only the scope of the claims.

In addition, in the present specification, in the case where an element is mentioned to be formed “on” another element, it means not only that one element is directly formed “on” another element, but also that other element(s) is interposed between them.

In the present specification, when a part is referred to as “comprising” an element, it is to be understood that the part may comprise other elements as well, rather than exclude other elements, unless otherwise indicated.

All numbers and expressions related to the quantities of components, reaction conditions, and the like used herein are to be understood as being modified by the term “about,” unless otherwise indicated.

In the present specification, each of the terms “film” and “thin film” refers to both “film” and “thin film,” unless otherwise specified.

In the present specification, the term “alkyl” or “alkyl group” covers linear or branched alkyl groups and all possible isomers thereof. For example, the alkyl or alkyl group covers not only a methyl group (Me), an ethyl group (Et), a normal propyl group (nPr), an isopropyl group (iPr), a normal butyl group (nBu), an isobutyl group (iBu), a tert-butyl group (tert-Bu, tBu), sec-butyl group (secBu), and the like, but also isomers thereof, and the like, but it is not limited thereto.

### [Method for Forming a Silicon-Containing Film]

According to an embodiment of the present invention, there is provided a method for forming a silicon-containing film, which comprises depositing a silicon-containing film using a composition for forming a silicon-containing film comprising a silicon precursor compound represented by Formula 1:

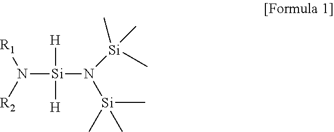

In Formula 1,
R₁ and R₂ are each independently selected from the group consisting of hydrogen and a linear or branched C₁-C₄ alkyl group, or
R₁ and R₂ are directly or indirectly connected to each other to form a substituted or unsubstituted C₄-C₉ cyclic group, wherein the C₄-C₉ cyclic group comprises one or two nitrogen (N) atoms and zero to two oxygen (O) atoms.

As an example, R₁ and R₂ in Formula 1 may each independently be selected from the group consisting of hydrogen, a methyl group, an ethyl group, a normal-propyl group, an isopropyl group, a normal-butyl group, an isobutyl group, a tert-butyl group, and a sec-butyl group.

As another example, in Formula 1, R₁ and R₂ are directly or indirectly connected to each other (together with the N atom to which they are bound) to form a substituted or unsubstituted C₄-C₉ cyclic group, wherein the cyclic group comprises one or two nitrogen (N) atoms and 0 to 2 oxygen (O) atoms. Specific examples of the C₄-C₉ cyclic group include an azetidinyl group, a pyrrolidinyl group, a piperidinyl group, a piperazineyl group, a morpholinyl group, and an azepanyl group. The C₄-C₉ cyclic group may have one or more, for example, 1 to 3 substituents. The substituent that the C₄-C₉ cyclic group may have may be, for example, at least one selected from the group consisting of a C₁-C₆ alkyl group, a halogen element (F, Cl, Br, and I), a hydroxyl group (OH), and a C₁-C₆ alkoxy, but it is not limited thereto.

Specifically, the method for forming a silicon-containing film may comprise depositing a silicon-containing film on a substrate using a composition for forming a silicon-containing film comprising the silicon precursor compound represented by the above Formula 1 by chemical vapor deposition (CVD) or atomic layer deposition (ALD). The silicon-containing film may comprise at least one selected from the group consisting of a silicon-containing oxide film and a silicon-containing composite metal oxide film. The deposition may be carried out at a temperature of 600° C. or higher, specifically, 600° C. to 850° C.

In an embodiment, the silicon-containing film may be formed at a temperature of 600° C. to 850° C. by chemical vapor deposition (CVD) or atomic layer deposition (ALD).

According to the method for forming a silicon-containing film according to an embodiment of the present invention, it is possible to efficiently form a silicon-containing film comprising at least one selected from the group consisting of a silicon-containing oxide film and a silicon-containing composite metal oxide film using a composition for forming a silicon-containing film comprising a silicon precursor compound having a specific structure represented by the above Formula 1 at a high temperature of 600° C. or higher. It is possible to precisely control the desired film thickness and composition and to form a uniform silicon-containing film with excellent coverage even on a substrate having a complex shape.

In particular, the method for forming a silicon-containing film of the present invention has a technical significance in that it can be applied to various fields such as moisture penetration barriers of memory devices, logic devices, display devices, and organic light emitting diode (OLED) devices, and a film of a desired thickness can be obtained at a high temperature of 600° C. or higher during film deposition.

In addition, the present invention provides a composition for forming a silicon-containing film, which comprises a silicon precursor compound represented by the above Formula 1 and used for depositing a silicon-containing film by chemical vapor deposition (CVD) or atomic layer deposition (ALD) at a temperature of 600° C. or higher, wherein the silicon-containing film comprises at least one selected from the group consisting of a silicon-containing oxide film and a silicon-containing composite metal oxide film.

Specifically, in the method for forming a silicon-containing film, the formation of a silicon-containing film may comprise depositing a silicon-containing film using the composition for forming a silicon-containing film comprising the silicon precursor compound represented by the above Formula 1 on a substrate (board).

The substrate may be a silicon semiconductor wafer, a compound semiconductor wafer, or a plastic substrate (PI, PET, or PES), but it is not limited thereto. In addition, a substrate having holes or grooves may be used, and a porous substrate having a large surface area may be used.

In particular, it is possible to produce an excellent effect of forming a silicon-containing film having a uniform thickness of several nanometers (nm) to several micrometers (μm) even on a substrate having patterns (grooves) on its surface, a porous substrate, or a plastic substrate in a temperature range of 600° C. or higher, specifically, 600° C. to 850° C.; and uniformly forming a silicon-containing film on a substrate, covering the deepest surface of fine patterns (grooves) and the upper surface having at least one of the fine irregularities (grooves) having an aspect ratio of 1 or more, for example, about 1 to 50 or more, and a width of 1 μm or less, for example, about 1 μm to 10 nm or less. For example, the silicon-containing film may be formed on a substrate having at least one irregularity having an aspect ratio of 1 or more and a width of 1 μm or less.

The deposition method of a silicon-containing film may use any methods and apparatuses known in the art to which the present invention pertains; if necessary, it may be carried out using one or more additional reactant gases or the like.

The deposition method of a silicon-containing film may be carried out by CVD, for example, organometallic chemical vapor deposition (MOCVD), or ALD. The MOCVD or ALD may be carried out using a deposition apparatus, deposition conditions, and reactive gases known in the art.

Specifically, a substrate is accommodated in a reaction chamber, the composition for forming a silicon-containing film comprising the silicon precursor compound is then transferred onto the substrate using a transport gas or a diluent gas, and a silicon-containing film is deposited at a deposition temperature of 600° C. or higher, specifically, 600° C. to 850° C.

Here, the deposition temperature of the above range allows it to be applied to memory devices, logic devices, and display devices. Since the process temperature is broad, it can be applied to various fields. In particular, as the composition for forming a silicon-containing film comprising the silicon precursor compound that is resistant to stress and capable of forming a dense film at a high temperature is used, deposition is readily carried out in the above deposition temperature range.

In addition, it is preferable to use at least one mixed gas selected from the group consisting of argon (Ar), nitrogen (N₂), helium (He), and hydrogen (H₂) as the transport gas or diluent gas.

In addition, the method for forming a silicon-containing film may comprise supplying the silicon precursor compound into a reaction chamber using at least one method selected from the group consisting of a bubbling method; a liquid delivery system (LDS) method; a vapor flow control (VFC) method; and a bypass method.

Specifically, the method of delivering the silicon precursor compound into a reaction chamber may be at least one method selected from the group consisting of a bubbling method in which the composition for forming a silicon-containing film comprising the silicon precursor compound is forcibly vaporized using a transport gas or a diluent gas; a liquid delivery system (LDS) method for supplying it in a liquid phase at room temperature to be vaporized through a vaporizer; a vapor flow control (VFC) method for directly supplying the precursor using its vapor pressure; and a bypass method for vaporization by heating.

For example, if the vapor pressure is high, a vapor flow control method may be used. If the vapor pressure is low, a bypass method of vaporization by heating the vessel or a method of bubbling using argon (Ar) or nitrogen (N₂) gas may be used to supply the composition for forming a silicon-containing film comprising the silicon precursor compound into a reaction chamber.

In an embodiment, the step of supplying the silicon precursor compound into a reaction chamber may be carried out using a transport gas or a diluent gas in a temperature range of room temperature to 150° C. and 0.1 to 10 Torr.

More specifically, the delivery method comprises a bubbling method or a bypass method, in which the bubbling method may be carried out using a transport gas or a diluent gas in a temperature range of room temperature to 150° C. and 0.1 Torr to 10 Torr, and the bypass method may be carried out using a vapor pressure of 0.1 Torr to 1.5 Torr in a temperature range of room temperature to 100° C. For example, the supply of the composition for forming a silicon-containing film comprising the silicon precursor compound into a reaction chamber may be carried out using a transport gas or a diluent gas in a temperature range of room temperature to 100° C. and 0.1 Torr to 10 Torr.

In addition, in order to vaporize the composition for forming a silicon-containing film comprising the precursor compound, for example, argon (Ar) or nitrogen (N₂) gas may be used for the transportation thereof. Alternatively, during the deposition, thermal energy or plasma may be used, or a bias may be applied to the substrate.

Meanwhile, according to the method of forming a silicon-containing film, in order to deposit at least one silicon-containing film selected from the group consisting of a silicon-containing oxide film and a silicon-containing composite metal oxide film, at least one selected from the group consisting of water vapor (H₂O), oxygen (O₂), oxygen plasma (O₂ plasma), hydrogen peroxide (H₂O₂), and ozone (O₃) may be used during deposition.

The at least one silicon-containing film selected from the group consisting of a silicon-containing oxide film and a silicon-containing composite metal oxide film may comprise at least one selected from the group consisting of, for example, HfSiOₓ, ZrSiOₓ, TiSiOₓ, HfAlOₓ, ZrAlSiOₓ, TiAlSiOₓ, ZrHfSiOₓ, ZrHfAlSiOₓ, SiC, and SiCO, but it is not limited thereto. Here, x may be 1 to 3.

The composition for forming a silicon-containing film, which comprises the silicon precursor compound represented by the above Formula 1, will be described below in detail.

### [Composition for Forming a Silicon-Containing Film]

The present invention provides a composition for forming a silicon-containing film, which comprises a silicon precursor compound represented by the above Formula 1.

Specifically, the composition for forming a silicon-containing film comprises a silicon precursor compound represented by the above Formula 1 and can be used for depositing a silicon-containing film by chemical vapor deposition (CVD) or atomic layer deposition (ALD) at a temperature of 600° C. or higher, wherein the silicon-containing film comprises at least one selected from the group consisting of a silicon-containing oxide film and a silicon-containing composite metal oxide film.

As the composition for forming a silicon-containing film according to an embodiment of the present invention comprises the silicon precursor compound having a specific structure represented by the above Formula 1, it is possible to form a uniform silicon-containing film, specifically a silicon-containing oxide film, having excellent coverage even on a substrate having a complex shape.

In particular, the above Formula 1 has a structure in which an amine having excellent reactivity with a surface of Si and thermally stable alkyl groups are bonded and has a structure containing three Si atoms; thus, it may be more advantageous for forming a stable silicon-containing film with a high deposition rate at a high temperature of about 600° C. to 850° C.

That is, in the silicon precursor compound represented by the above Formula 1, first, the amine represented by —NR₁R₂ in the structure has excellent reactivity with a surface such as Si, Si—OH, and Si—O, which is advantageous for forming a silicon-containing oxide film; second, a plurality of thermally stable bonds of Si and CH₃ are present in the structure, allowing the silicon precursor to form a stable film without rapid decomposition thereof at a high temperature of 600° C. or higher, so that it may be suitable for a three-dimensional NAND flash memory process that requires a uniform and dense silicon-containing film with excellent coverage at high temperatures; and third, the structure has a significantly greater GPC in SiO₂ ALD than that of the conventionally known silicon precursor compounds containing three Si atoms, so that it may be suitable for a three-dimensional NAND flash memory process in which a thick SiO₂ film is to be formed at high temperatures.

Specifically, R₁ and R₂ are each independently selected from the group consisting of hydrogen and a linear or branched C₁-C₄ alkyl group, or R₁ and R₂ are directly or indirectly connected to each other to form a substituted or unsubstituted C₄-C₉ cyclic group, wherein the C₄-C₉ cyclic group comprises one or two nitrogen (N) atoms and zero to two oxygen (O) atoms.

The silicon precursor compound may comprise one or more selected from the group consisting of compounds represented by Formulae 1-1 to 1-10:

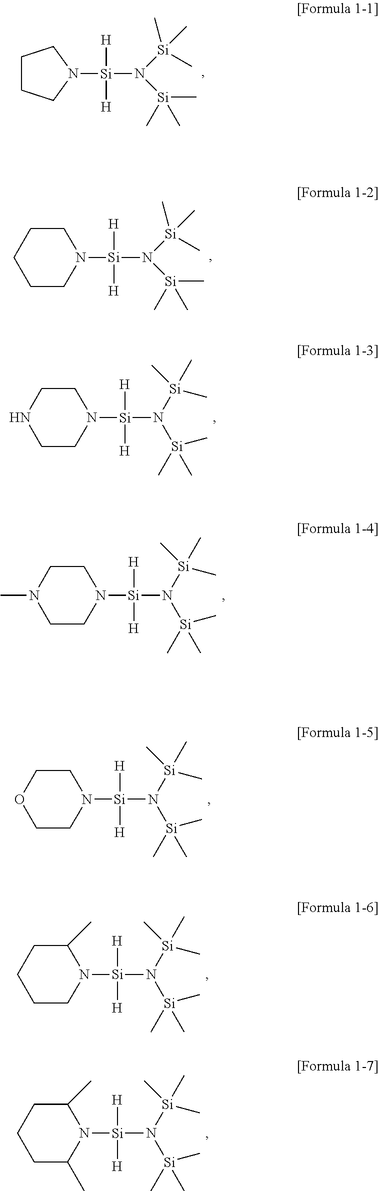

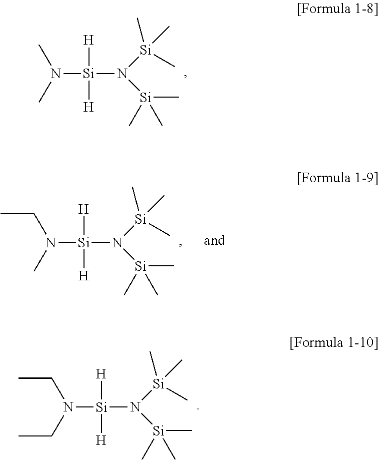

According to an embodiment of the present invention, when a deposition is carried out by ALD using the composition for forming a silicon-containing film, it may have a growth per cycle (GPC) of ALD gas supply of 1.5 to 4.5 Å/cycle in a temperature range of 600° C. to 850° C.

Specifically, when a SiO₂ film is formed by ALD using the composition for forming a silicon-containing film, the growth per cycle (GPC) of ALD gas supply may be 1.5 to 4.5 Å/cycle in a temperature range of 600° C. to 850° C.

For example, when a deposition is carried out by ALD using the composition for forming a silicon-containing film, it is possible to achieve a growth per cycle (GPC) of ALD gas supply of, for example, 1.5 to 4.0 Å/cycle, 1.7 to 4.0 Å/cycle, 2.0 to 4.0 Å/cycle, 1.5 to 3.5 Å/cycle, 1.7 to 3.5 Å/cycle, 1.5 to 3.0 Å/cycle, or 2.0 to 3.0 Å/cycle in a temperature range of 600° C. to 850° C., for example, 800° C.

When a silicon-containing film is formed using the composition for forming a silicon-containing film according to an embodiment of the present invention, it is possible to control the composition to achieve a desired film thickness and a desired silicon content and to form a uniform film having excellent coverage even on a substrate having patterns (grooves) on its surface, a porous substrate, a plastic substrate, or a substrate having a complex shape of a three-dimensional structure, whereby it is possible to provide a silicon-containing film with high quality.

In addition, it is possible to efficiently form at least one selected from the group consisting of a silicon-containing nitride film, a silicon-containing carbide film, and a silicon-containing composite metal film, in addition to a silicon-containing film comprising at least one selected from the group consisting of a silicon-containing oxide film and a silicon-containing composite metal oxide film, on a substrate by CVD or ALD using the composition for forming a silicon-containing film.

In particular, according to an embodiment of the present invention, when a silicon-containing film comprising at least one selected from the group consisting of a silicon-containing oxide film and a silicon-containing composite metal oxide film is formed on a substrate by ALD using the composition for forming a silicon-containing film, there are great advantages in that a film having a desired thickness can be obtained with a uniform thickness at a high temperature of 600° C. or higher, the film shrinkage and the wet etch rate at a high temperature are lower, and a pure silicon-containing film of high quality with less impurities can be formed.

### [Silicon Precursor Compound]

The present invention provides a silicon precursor compound represented by Formula 0 or Formula 1:

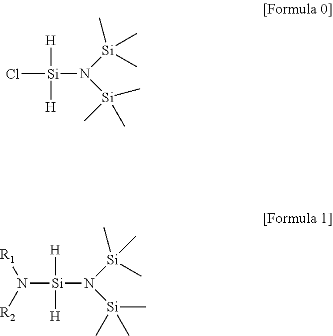

In Formula 1,
R₁ and R₂ are each independently selected from the group consisting of hydrogen and a linear or branched C₁-C₄ alkyl group, or
R₁ and R₂ are directly or indirectly connected to each other to form a substituted or unsubstituted C₄-C₉ cyclic group, wherein the C₄-C₉ cyclic group comprises one or two nitrogen (N) atoms and zero to two oxygen (O) atoms.

The compounds of Formulae 0 and 1 may be used in the formation of a silicone-containing film.

Specifically, the compound of Formula 0 may be used for the preparation of the compound of Formula 1, and a composition for forming a silicone-containing film comprising the compound of Formula 1 may be used for the deposition of a silicone-containing film.

Therefore, the present invention provides a use of the silicon precursor compound represented by the above Formula 1 for forming a silicone-containing film.

The silicon precursor compound may be selected from the group consisting of compounds represented by the above Formulae 1-1 to 1-10.

The silicon-containing film may be formed at a temperature of 600° C. to 850° C. by chemical vapor deposition (CVD) or atomic layer deposition (ALD).

In addition, when a SiO₂ film is formed by an atomic layer deposition (ALD) method using the silicon precursor compound, the growth per cycle of ALD gas supply is 1.5 to 4.5 Å/cycle in a temperature range of 600° C. to 850° C.

In addition, the silicon-containing film may be formed by a method comprising supplying the silicon precursor compound into a reaction chamber using at least one method selected from the group consisting of a bubbling method; a liquid delivery system (LDS) method; a vapor flow control (VFC) method; and a bypass method.

In addition, the step of supplying the silicon precursor compound into a reaction chamber may be carried out using a transport gas or a diluent gas in a temperature range of room temperature to 150° C. and 0.1 to 10 Torr.

In addition, the silicon precursor compound is used for the deposition of a silicon-containing film. During the deposition, thermal energy or plasma may be used, or a bias may be applied to the substrate.

In addition, the silicon-containing film comprises at least one selected from the group consisting of a silicon-containing oxide film and a silicon-containing composite metal oxide film, the silicon precursor compound is used for the deposition of a silicon-containing film, and at least one selected from the group consisting of water vapor (H₂O), oxygen (O₂), oxygen plasma (O₂ plasma), hydrogen peroxide (H₂O₂), and ozone (O₃) may be used during the deposition.

In addition, the silicon-containing film may be formed in a thickness range of 1 nm to 500 nm.

In addition, the silicon-containing film may be formed on a substrate having at least one irregularity having an aspect ratio of 1 or more and a width of 1 μm or less.

### [Method for Preparing a Silicon Precursor Compound]

Meanwhile, the silicon precursor compound represented by the above Formula 1 may be prepared by various methods.

The method for preparing a silicon precursor compound (Formula 1) according to an embodiment of the present invention may comprise subjecting a hexamethyldisilazane metal salt represented by the following Formula A to a halide-hexamethyldisilazane substitution reaction with a dihalide silicon precursor compound represented by the following Formula B to form a compound represented by the following Formula C; and subjecting the compound represented by the following Formula C to a halide-amine substitution reaction with a dialkylamine or cyclic amine represented by the following Formula D to form a compound represented by the following Formula 1:

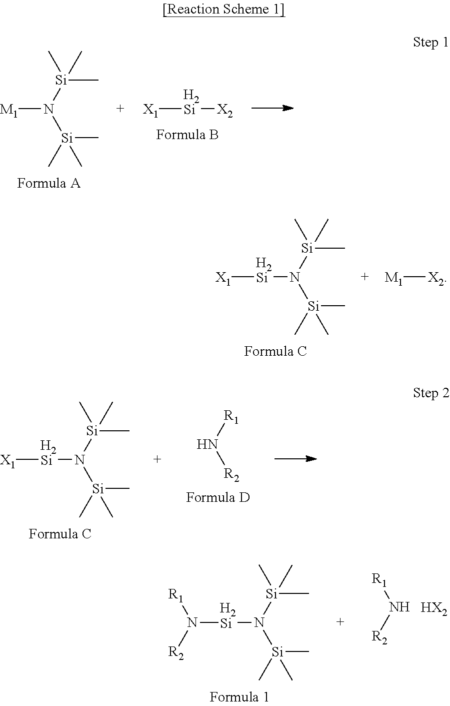

In Reaction Scheme 1,
M1 is an alkali metal and Li or Na,
R₁ and R₂ are each independently selected from the group consisting of hydrogen and a linear or branched C₁-C₄ alkyl group, or
R₁ and R₂ are directly or indirectly connected to each other to form a substituted or unsubstituted C₄-C₉ cyclic group, wherein the C₄-C₉ cyclic group comprises one or two nitrogen (N) atoms and zero to two oxygen (O) atoms, and
X₁ and X₂ are each independently a halogen element and Cl, Br, or I.

According to another example, the silicon precursor compound of the above Formula 1 can be obtained by using the silicon precursor compound represented by Formula 0.

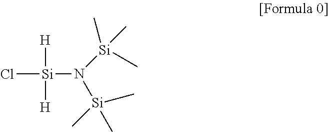

Specifically, the silicon precursor compound represented by the above Formula 1 can be readily synthesized by reacting the silicon precursor compound of the above Formula 0 with a secondary amine.

The silicon precursor compound of the above Formula 0 can be readily synthesized using dichlorosilane (SiH₂Cl₂) and hexamethyldisilazane (1,1,1,3,3,3-hexamethyldisilazane) as raw materials that are commercially available and cheap. The silicon precursor compound of the above Formula 0 may be used for the purpose of preparing the silicon precursor compound of the above Formula 1.

Referring to Reaction Scheme 1 above, for the preparation of the silicon precursor compound (Formula 1), 0.5 to 2 moles of a dihalide silicon precursor compound (Formula B) is added to a hexamethydisilazane metal salt (Formula A) at a low temperature (about −30° C. to −5° C.) to carry out a first substitution reaction of halide and hexamethydisilazane. Next, the metal halide salt contained in the reaction product as a reaction by-product is removed through a filter, and the remaining product may be purified to obtain a compound represented by Formula C. Thereafter, 1 to 3 moles of a dialkylamine or a cyclic amine (Formula D) is added to the compound represented by Formula C at a low temperature (about −30° C. to −5° C.) to carry out a substitution reaction of halide and amine. Next, the dialkylamine halide salt or a cyclic amine halide salt contained in the reaction product as a reaction by-product is removed through a filter, and the remaining product may be purified to obtain the silicon precursor compound represented by Formula 1.

The first and second halide-amine substitution reactions may be carried out in a solvent at 0° C. to 30° C., specifically 20° C. to 30° C., for example, at room temperature for 2 to 30 hours.

In addition, the solvent may comprise at least one selected from the group consisting of an alkane having 5 to 8 carbon atoms, toluene, ethers, tetrahydrofuran, and mono- to tetra-ethylene glycol dimethyl ethers.

According to an embodiment of the present invention, the silicon precursor compound may be used to obtain a composition for forming a silicon-containing film comprising the silicon precursor compound.

### [Silicon-Containing Film]

According to an embodiment of the present invention, there is provided a silicon-containing film formed using a composition for forming a silicon-containing film comprising the silicon precursor compound represented by the above Formula 1.

Specifically, there is provided a silicon-containing film formed using a composition for forming a silicon-containing film comprising the silicon precursor compound represented by the above Formula 1.

The silicon-containing film may have a thickness of several nanometers (nm) to several micrometers (μm) and may be variously applied depending on the application purposes. Specifically, the silicon-containing film may be formed in a thickness range of 1 nm to 500 nm.

The silicon-containing film may be formed on a substrate (board).

The substrate is as described above.

The silicon-containing film may comprise at least one selected from the group consisting of a silicon-containing oxide film and a silicon-containing composite metal oxide film.

In addition, it is possible to efficiently form at least one selected from the group consisting of a silicon-containing oxide film and a silicon-containing composite metal oxide film using a composition for forming a silicon-containing film comprising the silicon precursor compound represented by Formula 1.

In addition, as the silicon-containing film is prepared by using a composition for forming a silicon-containing film comprising a silicon precursor compound having excellent thermal stability, the silicon-containing film is characterized in that it has a low shrinkage rate even at a high temperature of 600° C. or higher, for example, 600° C. to 850° C., and a low wet etch rate (A/s).

Specifically, the silicon-containing film may have a shrinkage (S₇₅₀) of 5.0% or less as represented by the following Equation 1:

$$Shrinkage ( {S}_{750} , \% ) = \frac{A - B}{A} \times 100 \qquad [ Equation 1 ]$$

In Equation 1,
A is the initial thickness (Å) of a silicon-containing film formed by ALD at 750° C., and
B is the thickness (Å) of the silicon-containing film formed by ALD at 750° C. after it is left at 750° C. in an argon (Ar) atmosphere for 60 minutes.

The shrinkage (S₇₅₀) of the silicon-containing film as represented by Equation 1 may be, for example, 4.8% or less, 4.5% or less, 4.4% or less, 4.0% or less, 3.9% or less, 3.8% or less, 3.5% or less, 3.4% or less, 3.3% or less, 3.2% or less, 3.0% or less, 2.5% or less, 2.0% or less, 1.5% or less, 1.2% or less, 1.1% or less, or 1.0% or less. Specifically, the shrinkage (S₇₅₀) of the silicon-containing film as represented by Equation 1 may be 4.8% to 0.5%, 3.5% to 0.5%, 3.0% to 0.5%, or 2.5% to 0.5%.

When the silicon-containing film has a shrinkage (S₇₅₀) satisfying the above range, it may be advantageous for forming a uniform and dense silicon-containing film.

Meanwhile, when the silicon-containing film is formed by deposition at 750° C. to a thickness of 500 Å, and when the thickness of the silicon-containing film is measured with an ellipsometer before and after the silicon-containing film is exposed to an etching solution of 1% dilute hydrofluoric acid, the wet etch rate (Å/s) of the silicon-containing film represented by the following Equation 2 may be 4.0 Å/s or less:

$$Wet etch rate ( Å / s ) = etch thickness change ( Δ E , Å ) / 30 s \qquad [ Equation 2 ]$$

The etch thickness change (ΔE) may be represented by the following Equation 2-1:

$$Etch thickness change ( Δ E , Å ) = {E}_{A} - {E}_{B} \qquad [ Equation 2 - 1 ]$$

In Equation 2-1,
E_{A} is the initial thickness (Å) of a silicon-containing film formed by ALD at 750° C., and
E_{B} is the thickness (Å) of the silicon-containing film formed by ALD at 750° C. after it is etched in a 1% dilute HF solution for 30 seconds.

In Equation 2, “s” means seconds.

The wet etch rate (Å/s) of the silicon-containing film as represented by Equation 2 may be, for example, 3.8 Å/s or less, 3.5 Å/s or less, 3.2 Å/s or less, 3.0 Å/s or less, less than 2.9 Å/s, 2.8 Å/s or less, 2.7 Å/s or less, 2.6 Å/s or less, 2.55 Å/s or less, 2.51 Å/s or less, 2.5 Å/s or less, 2.45 Å/s or less, 2.4 Å/s or less, 2.2 Å/s or less, 2.1 Å/s or less, 2.0 Å/s or less, 1.5 Å/s or less, 1.0 Å/s or less, 0.95 Å/s or less, 0.5 Å/s or less, 0.1 Å/s or less, 0.05 Å/s or less, or 0.03 Å/s or less.

Specifically, the wet etch rate (Å/s) of the silicon-containing film as represented by Equation 2 may be 3.8 Å/s to 0.5 Å/s, 3.5 Å/s to 0.5 Å/s, 3.0 Å/s to 0.5 Å/s, 2.8 Å/s to 0.5 Å/s, 2.7 Å/s to 0.5 Å/s, 2.6 Å/s to 0.5 Å/s, 2.51 Å/s to 0.5 Å/s, 2.5 Å/s to 0.5 Å/s, 2.1 Å/s to 0.5 Å/s, 2.0 Å/s to 0.5 Å/s, 1.5 Å/s to 0.5 Å/s, 1.2 Å/s to 0.5 Å/s, or 1.0 Å/s to 0.5 Å/s.

When the silicon-containing film has a wet etch rate (Å/s) satisfying the above range, it may be advantageous for forming a uniform and dense silicon-containing film.

In addition, the silicon-containing film may be very excellent in step coverage.

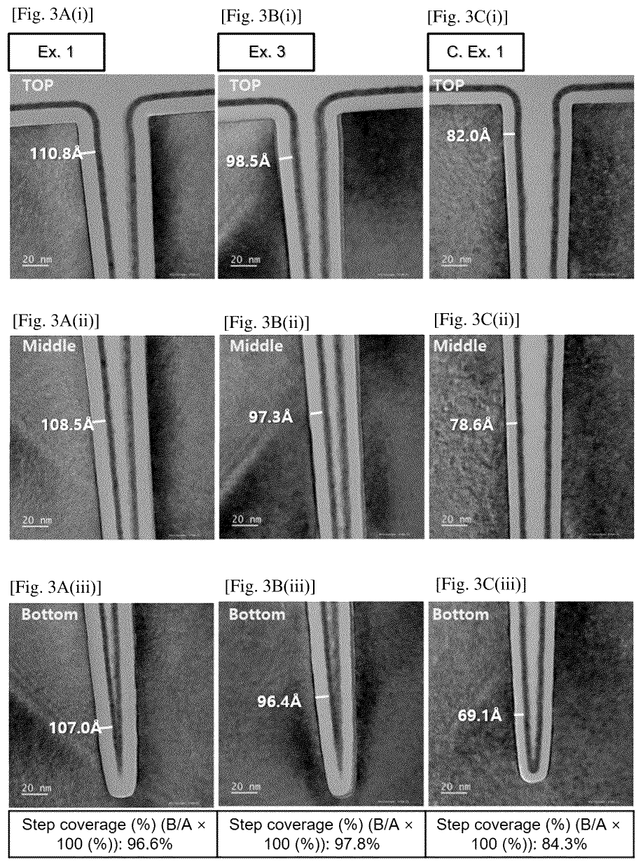

Specifically, a silicon-containing film is deposited on a substrate having a stepped groove pattern as shown in FIG. 3 and then analyzed using a transmission electron microscope (TEM). Then, the step coverage can be calculated as shown in the following Equation 3.

$$Step coverage ( \% ) = B / A \times 100 ( \% ) \qquad [ Equation 3 ]$$

in Equation 3,
A is the thickness (Å) measured at the top of the groove, and
B is the thickness (Å) measured at the bottom of the groove.

The silicon-containing film may have a step coverage (%) of, for example, 80% or more, 82% or more, 85% or more, 90% or more, 92% or more, 92.5% or more, 92.9% or more, 93% or more, 95% or more, or 96% or more. As a specific example, the step coverage (%) of the silicone-containing film may be 80% to 99%, 85% to 99%, or 95% to 99%.

When the silicon-containing film has a step coverage (%) satisfying the above range, a high step ratio and fine thickness control are possible, so that it can be advantageously used to fabricate various semiconductor devices such as DRAM and 3D NAND flash memory.

### MODE FOR THE INVENTION

Hereinafter, the present invention will be described in detail with reference to examples. The following examples are only illustrative of the present invention, and the scope of the present invention is not limited thereto.

### <Example 0> Preparation of chloro-(hexamethyldisilyl)amino-silane: [ClSiH₂{N(SiMe₃)₂}]

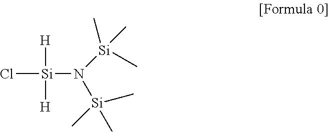

About 910.02 g (2.5 M, about 3.267 moles) of a normal-butyllithium hexane solution (n-BuLi in n-hexane) was mixed with about 4,000 ml of anhydrous hexane in a 20-liter round bottom flask. About 575.27 g (about 3.564 moles) of hexamethyldisilazane (1,1,1,3,3,3-hexamethyldisilazane) was added thereto at about −20° C., and the temperature was then gradually raised to room temperature under stirring, followed by stirring thereof for 4 hours. About 330 g (about 3.267 moles) of dichlorosilane was slowly added to the lithium (1,1,1,3,3,3-hexamethyldisilazane) salt thus formed at −20° C. to −10° C., and the temperature was then gradually raised to room temperature under stirring, followed by stirring thereof for 17 hours. Upon completion of the reaction, the salt formed during the reaction was removed through filtration, and the solvent and volatile side reactants were removed by vacuum distillation to obtain 637 g (yield: 95.00%) of chloro-(hexamethyldisilyl)amino-silane [ClSiH₂{N(SiMe₃)₂}] as a colorless liquid compound represented by Formula 0, which was used in Examples 1 to 5.

¹H-NMR (C₆D₆): δ 0.165 (N—Si—CH₃, s, 18H), δ 5.148 (Si—H₂, s, 2H)

### <Example 1> Preparation of pyrrolidinyl-(hexamethyldisilyl)amino-silane and a Composition for Forming a Silicone-Containing Film Comprising the Same: [(CH₂CH₂CH₂CH₂N)SiH₂{N(SiMe₃)₂}]

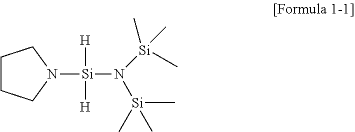

About 18.73 g (0.083 mole) of chloro-(hexamethyldisilyl)amino-silane obtained in Example 0 above was mixed with about 1,000 ml of anhydrous hexane in a 2-liter round bottom flask. About 12.97 g (about 0.182 mole) of pyrrolidine was added thereto at about −20° C., and the temperature was then gradually raised to room temperature under stirring, followed by stirring thereof for 18 hours. Upon completion of the reaction, the salt formed during the reaction was removed through filtration, and the solvent and volatile side reactants were removed by vacuum distillation to obtain 75 g (yield: 74.29%) of pyrrolidinyl-(hexamethyldisilyl)amino-silane [(CH₂CH₂CH₂CH₂N)SiH₂{N(SiMe₃)₂}] as a colorless liquid compound represented by Formula 1-1, which was used for a composition for forming a film.

b.p.: 40° C. at 0.3 Torr (223.4° C. at 760 Torr)

¹H-NMR (C₆D₆): δ 0.268 (N—Si—CH₃, s, 18H), δ 1.509 (N—CH₂—CH₂, m, 4H), δ 2.956 (N—CH₂—CH₂, m, 4H), δ 4.983 (Si—H₂, s, 2H)

### <Example 2> Preparation of piperidinyl-(hexamethyldisilyl)amino-silane and a Composition for Forming a Silicone-Containing Film Comprising the Same: [(CH₂CH₂CH₂CH₂CH₂N)SiH₂{N(SiMe₃)₂}]

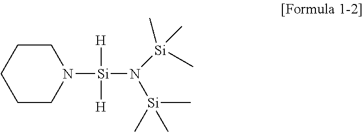 [SMILES: C[Si](C)(C)N([SiH2]N1CCCCC1)[Si](C)(C)C]

About 53.07 g (yield: about 95%) of piperidinyl-(hexamethyldisilyl)amino-silane [(CH₂CH₂CH₂CH₂CH₂N)SiH₂{N(SiMe₃)₂}] as a colorless liquid compound represented by Formula 1-2 was obtained in the same manner as in Example 1, except that piperidine was used instead of pyrrolidine, and it was used for the composition for forming a film.

b.p.: 87° C. at 5.5 Torr (227.8° C. at 760 Torr)

¹H-NMR (C₆D₆): δ 0.268 (N—Si—CH₃, s, 18H), δ 1.338 (N—CH₂—CH₂—CH₂, m, 4H), δ 1.432, 1.445 (N—CH₂—CH₂—CH₂, m, 2H), δ 2.848 (N—CH₂—CH₂—CH₂, t, 4H), δ 4.860 (Si—H₂, s, 2H)

### <Example 3> Preparation of dimethylamino-(hexamethyldisilyl)amino-silane and a Composition for Forming a Silicone-Containing Film Comprising the Same: [{(CH₃)₂N}SiH₂{N(SiMe₃)₂}]

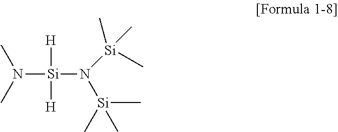

About 40.0 g (yield: about 85%) of dimethylamino-(hexamethyldisilyl)amino-silane [{(CH₃)₂N}SiH₂{N(SiMe₃)₂}] as a colorless liquid compound represented by Formula 1-8 was obtained in the same manner as in Example 1, except that dimethylamine was used instead of pyrrolidine, and it was used for the composition for forming a film.

b.p.: 69° C. at 13 Torr (186.5° C. at 760 Torr)

¹H-NMR (C₆D₆): δ 0.242 (N—Si—CH₃, s, 18H), δ 2.407 (N—CH₃, s, 6H), δ 4.837 (Si—H₂, s, 2H)

### <Example 4> Preparation of ethylmethylamino-(hexamethyldisilyl)amino-silane and a Composition for Forming a Silicone-Containing Film Comprising the Same: [{(CH₃CH₂)(CH₃)N}SiH₂{N(SiMe₃)₂}]

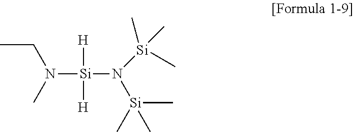

About 175.12 g (yield: about 79.6%) of ethylmethylamino-(hexamethyldisilyl)amino-silane [{(CH₃CH₂)(CH₃)N}SiH₂{N(SiMe₃)₂}] as a colorless liquid compound represented by Formula 1-9 was obtained in the same manner as in Example 1, except that ethylmethylamine was used instead of pyrrolidine, and it was used for the composition for forming a film.

b.p.: 68° C. at 9 Torr (192.1° C. at 760 Torr)

¹H-NMR (C₆D₆): δ 0.255 (N—Si—CH₃, s, 18H), δ 0.973 (N—CH₂—CH₃, t, 3H), δ 2.417 (N—CH₃, s, 3H) 2.785 2.767 (N—CH₂—CH₃, q, 2H), δ 4.873 (Si—H₂, s, 2H)

### <Example 5> Preparation of diethylamino-(hexamethyldisilyl)amino-silane and a Composition for Forming a Silicone-Containing Film Comprising the Same: [{(CH₃CH₂)₂N}SiH₂{N(SiMe₃)₂}]

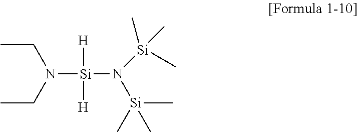

About 41.6 g (yield: about 79.5%) of diethylamino-(hexamethyldisilyl)amino-silane [{(CH₃CH₂)₂N}SiH₂{N(SiMe₃)₂}] as a colorless liquid compound represented by Formula 1-10 was obtained in the same manner as in Example 1, except that diethylamine was used instead of pyrrolidine, and it was used for the composition for forming a film.

b.p.: 75° C. at 6 Torr (210° C. at 760 Torr)

¹H-NMR (C₆D₆): δ 0.266 (N—Si—CH₃, s, 18H), δ 0.979 (N—CH₂—CH₃, t, 6H), δ 2.854 2.837 (N—CH₂—CH₃, q, 4H), δ 4.891 (Si—H₂, s, 2H)

### Comparative Example 1

Tris(dimethylamino)silane (3DMAS or TDMAS) [SiH(NMe₂)₃](manufactured by UP Chemical Co., Ltd.) was used.

### Comparative Example 2

### Preparation of pyrrolidinyl-(tetramethyldisilyl)amino-silane and a Composition for Forming a Silicone-Containing Film Comprising the Same: [(CH₂CH₂CH₂CH₂N)SiH₂{N(SiHMe₂)₂}]

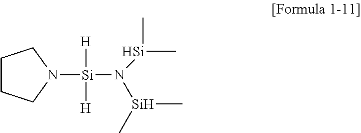

About 38 g (yield: about 65%) of pyrrolidinyl-(tetramethyldisilyl)amino-silane [(CH₂CH₂CH₂CH₂N)SiH₂{N(SiHMe₂)₂}] as a colorless liquid compound represented by Formula 1-11 was obtained in the same manner as in Example 1, except that tetramethyldisilazane (1,1,3,3-tetramethyldisilazane) was used instead of hexamethyldisilazane (1,1,1,3,3,3-hexamethyldisilazane), and it was used for the composition for forming a film.

b.p.: 32° C. at 0.3 Torr (210.3° C. at 760 Torr)

¹H-NMR (C₆D₆): δ 0.265, 0.273 (N—Si—CH₃, d, 12H), δ 1.502 (N—CH₂—CH₂, m, 4H), δ 2.973 (N—CH₂, m, 4H), δ 4.827 (N—Si—H, m, 2H), δ 4.981 (Si—H₂, s, 2H)

### Test Example

### <Test Example 1> Analysis of the Deposition Characteristics of the Composition for Forming a Silicon-Containing Film Comprising a Silicon Precursor Compound at High Temperatures

A composition for forming a silicon-containing film comprising each of the silicon precursor compounds of Examples 1 and 3 and Comparative Examples 1 and 2 and ozone (O₃) as a reaction gas were used to form a silicon-containing film by ALD.

First, a silicon substrate was immersed in a Piranha solution, in which sulfuric acid (H₂SO₄) and hydrogen peroxide (H₂O₂) had been mixed at a ratio of 4:1, for about 10 minutes and then taken out. It was then immersed in a dilute aqueous HF solution for 2 minutes to form a fresh surface. A silicon-containing oxide film was then formed on the silicon substrate by ALD.

The composition for forming a silicon-containing film comprising each of the silicon precursor compounds of Examples 1 and 3 and Comparative Examples 1 and 2 was contained in a stainless steel canister and used at room temperature or as heated. In Comparative Example 1, it was used at room temperature without heating. In Example 1 and 3 and Comparative Example 2, it was used as heated to 60° C. The composition for forming a film was supplied to the reaction chamber in a gaseous state by flowing argon (Ar) gas as a transport gas at a flow rate of about 200 sccm at a process pressure of about 4 Torr in the reactor.

In order to confirm the deposition characteristics of each silicon-containing oxide film, a silicon-containing oxide film was formed by repeating a gas supply cycle 100 times, in which cycle the composition for forming a film in a gaseous state was supplied for about 3 seconds; argon (Ar) gas was supplied for about 10 seconds to remove the composition for forming a film (gas) remaining in the reactor; ozone (O₃) was supplied as a reaction gas for about 5 seconds; and argon (Ar) gas was supplied for about 10 seconds to remove ozone (O₃) remaining in the reactor.

The thickness of each oxide film formed using the composition for forming a silicon-containing film prepared by the methods of the Examples and Comparative Examples was measured using an ellipsometer (M-2000, J.A. Woollam).

Thereafter, the measured thickness was divided by the number of gas supply cycles (100 times) to calculate the growth per cycle (GPC) of ALD gas supply.

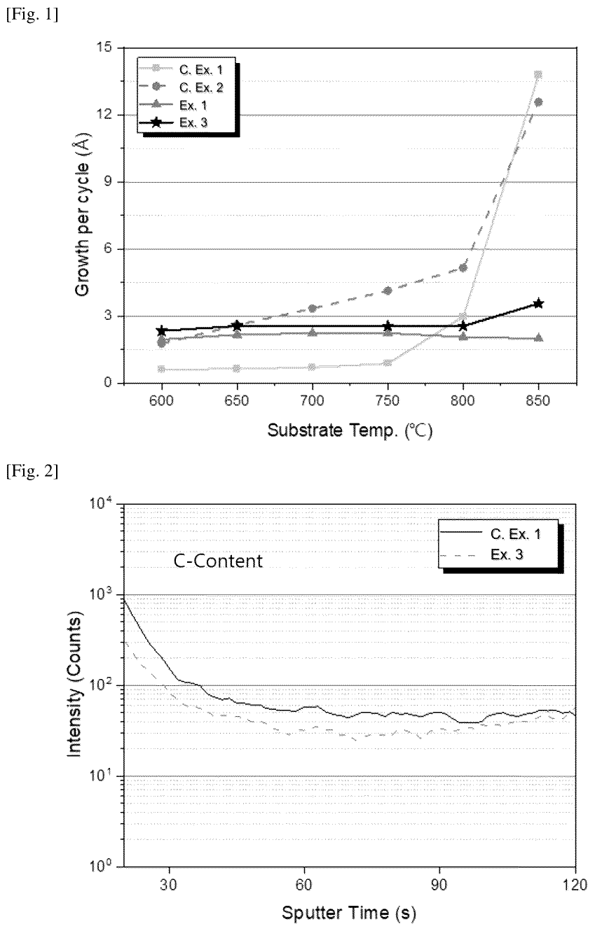

Specifically, the growth per cycle (GPC) of ALD gas supply with respect to a temperature (process temperature) of 600° C. to 850° C. was measured. The results are shown in FIG. 1 and Table 1.

TABLE 1

| Deposition | Growth per cycle of ALD gas supply (Å/cycle) | | | |
|---|---|---|---|---|
| Temp. | Ex. 1 | Ex. 3 | C. Ex. 1 | C. Ex. 2 |
| (° C.) | Formula 1-1 | Formula 1-8 | 3DMAS | Formula 1-11 |
| 600 | 1.95 | 2.33 | 0.62 | 1.76 |
| 650 | 2.16 | 2.55 | 0.64 | 2.59 |
| 700 | 2.23 | — | 0.71 | 3.33 |
| 750 | 2.23 | 2.54 | 0.88 | 4.13 |
| 800 | 2.06 | 2.54 | 2.97 | 5.15 |
| 850 | 1.99 | 3.55 | 13.78 | 12.57 |

As can be seen from Table 1 and FIG. 1, when ALD was carried out at a high temperature of 600° C. or higher using the composition for forming a silicone-containing film comprising the silicone compound of each of Examples 1 and 3, a constant GPC was achieved at a relatively high temperature of 600° C. to 850° C., as compared with the case where the composition for forming a silicone-containing film comprising the silicone compound of each of Comparative Examples 1 and 2 was used.

Specifically, when the composition for forming a silicon-containing film comprising the silicon precursor compound of Comparative Example 1 was used, the growth per cycle (GPC) of ALD gas supply increased from about 700° C. When the composition for forming a silicon-containing film comprising the silicon precursor compound of Comparative Example 2 was used, the growth per cycle (GPC) of ALD gas supply increased from about 650° C. In contrast, when the composition for forming a silicon-containing film comprising the silicon precursor compound of each of Examples 1 and 3 was used, the growth per cycle (GPC) of ALD gas supply was constant even at a high temperature of 800° C. or 850° C. It was confirmed from the above that the composition for forming a silicone-containing film comprising the silicone precursor compound of the Examples of the present invention achieves a constant GPC at a high temperature of 600° C. to 800° C. or 850° C. and shows self-limiting film growth characteristics; thus, it is a precursor suitable for an ALD process at high temperatures.

### <Test Example 2> Analysis of the Physical Properties of a Silicon-Containing Oxide Film Deposited at High Temperatures

The composition for forming a silicon-containing film comprising the silicon precursor compound of each of Examples 1 and 3 and Comparative Example 1 was used to form a SiO₂ film having the same thickness on a flat wafer at 750° C. while the ALD gas supply cycle was adjusted. Its physical and chemical properties were analyzed.

Specifically, the shrinkage and wet etch rate (WER, Å/s) of the SiO₂ film were measured. The thickness of the SiO₂ film was measured with an ellipsometer (M-2000, J.A. Woollam).

The thickness of the silicon-containing film (SiO₂ film) having an initial thickness of about 100 Å formed on a flat wafer at 750° C., as shown in Table 2 below, by adjusting the ALD gas supply cycle was compared with the thickness of the silicon-containing film (SiO₂ film) upon annealing in an argon (Ar) atmosphere at 750° C. for 60 minutes to calculate the shrinkage according to Equation 1.

$$Shrinkage ( {S}_{750} , \% ) = \frac{A - B}{A} \times 100 \qquad [ Equation 1 ]$$

In Equation 1,
A is the initial thickness (Å) of a silicon-containing film formed by ALD at 750° C., and
B is the thickness (Å) of the silicon-containing film formed by ALD at 750° C. after it is left at 750° C. in an argon (Ar) atmosphere for 60 minutes.

The results are shown in Table 2.

TABLE 2

| | Ex. 1 | Ex. 3 | C. Ex. 1 |
|---|---|---|---|
| Compound | Formula 1-1 | Formula 1-8 | 3DMAS |
| Initial thickness (Å) of a SiO₂ film formed by ALD | 101.32 | 103.41 | 101.80 |
| at 750° C. (A) | | | |
| Thickness (Å) of the SiO₂ film formed by ALD at | 97.92 | 100.97 | 95.28 |
| 750° C. after it was left at 750° C. for 60 minutes (B) | | | |
| Shrinkage (S₇₅₀, %) | 3.34 | 2.36 | 6.40 |

As can be seen from Table 2 above, the shrinkage of the silicon-containing oxide film (SiO₂ film) deposited using the composition for forming a silicon-containing film of each of Examples 1 and 3 was 3.34% and 2.36%, respectively. In contrast, the shrinkage of the silicon-containing oxide film deposited using the composition for forming a silicon-containing film of Comparative Example 1 was 6.40%. As such, the silicon-containing oxide film deposited using the composition for forming a silicon-containing film of each of Examples 1 and 3 had a smaller shrinkage than that of the silicon-containing oxide film deposited using the composition for forming a silicon-containing film of Comparative Example 1.

Meanwhile, the silicon-containing film (SiO₂ film) having an initial thickness of about 500 Å formed on a flat wafer at 750° C., as shown in Table 3 below, by adjusting the ALD gas supply cycle was etched in a dilute 1% HF solution for 30 seconds. The thickness change was measured to calculate the wet etch rate (WER, Å/s) according to Equation 2.

$$Wet etch rate ( Å / s ) = etch thickness change ( Δ E , Å ) / 30 s \qquad [ Equation 2 ]$$

The etch thickness change (ΔE) may be represented by the following Equation 2-1:

$$Etch thickness change ( Δ E , Å ) = {E}_{A} - {E}_{B} \qquad [ Equation 2 - 1 ]$$

In Equation 2-1,
E_{A} is the initial thickness (Å) of a silicon-containing film formed by ALD at 750° C., and
E_{B} is the thickness (Å) of the silicon-containing film formed by ALD at 750° C. after it is etched in a 1% dilute HF solution for 30 seconds.

In Equation 2, “s” means seconds.

The results are shown in Table 3 below.

TABLE 3

| | Ex. 3 | C. Ex. 1 |
|---|---|---|
| Compound | Formula 1-8 | 3DMAS |
| Initial thickness (Å) of a SiO2 film formed by ALD at 750° C. (E_{A}) | 497.0 | 503.4 |
| Thickness (Å) of the SiO₂ film formed by ALD at 750° C. after it was | 421.7 | 416.4 |
| etched in a dilute 1% HF solution for 30 seconds (E_{B}) | | |
| Wet etch rate (E_{A} − E_{B})/30 s (Å/s) | 2.51 | 2.90 |

As can be seen from Table 3 above, the wet etch rate of the silicon-containing oxide film (SiO₂ film) deposited using the composition for forming a silicon-containing film of Example 3 was 2.51 Å/s. In contrast, the wet etch rate of the silicon-containing oxide film deposited using the composition for forming a silicon-containing film of Comparative Example 1 was 2.90 Å/s. The silicon-containing oxide film deposited using the composition for forming a silicon-containing film of Example 3 was significantly decreased.

Meanwhile, in order to confirm impurities in the silicon-containing oxide film, secondary ion mass spectrometry (SIMS) was carried out for the silicon-containing oxide film.

FIG. 2 is a graph showing the results of secondary ion mass spectrometry (SIMS) of a silicon-containing oxide film deposited at a temperature of 750° C. using each of the compositions for forming a silicon-containing film of Example 3 and Comparative Example 1 of the present invention.

In order to confirm impurities in the silicon-containing oxide film deposited using the composition for forming a silicon-containing film of each of Comparative Example 1 and Example 3, the silicon-containing oxide film deposited to a thickness of about 100 Å was analyzed for a carbon (C) content by SIMS.

As a result, the carbon content was reduced by about 40.6% in Example 3 as compared with Comparative Example 1, indicating that a pure silicon-containing oxide film with less than 100 counts of a carbon component was formed.

FIG. 3 is a transmission electron microscope (TEM) image of a silicon-containing oxide film formed on a wafer with a deep pattern at 750° C. by ALD using the composition for depositing a silicon-containing film of each of Examples 1 and 3 and Comparative Example 1 of the present invention and ozone (O₃). Table 4 shows the thickness of the silicon-containing oxide film measured in the part shown in FIG. 3.

TABLE 4

| | Ex. 1 | Ex. 3 | C. Ex. 1 |
|---|---|---|---|
| Compound | Formula 1-1 | Formula 1-8 | 3DMAS |
| Thickness (Å) measured at the top of the groove (A) | 110.8 | 98.5 | 82.0 |
| Thickness (Å) measured in the middle of the groove | 108.5 | 97.3 | 78.6 |
| Thickness (Å) measured at the bottom of the groove (B) | 107.0 | 96.4 | 69.1 |
| Step coverage (%) (B/A × 100 (%)) | 96.6% | 97.8% | 84.3% |

As can be seen from Table 4, when the composition for forming a silicon-containing film of each of Examples 1 and 3 and Comparative Example 1 was deposited on a substrate having a step and then analyzed using TEM, the step coverage (%) of the silicon-containing oxide film deposited using the composition for forming a silicon-containing film each of Examples 1 and 3 was 96.6% and 97.8, respectively, whereas the step coverage of the silicon-containing oxide film deposited using the composition for forming a silicon-containing film of Comparative Example 1 was 84.3%. The silicon-containing oxide film deposited using the composition for forming a silicon-containing film of each of Examples 1 and 3 had a remarkably excellent step coverage as compared with the silicon-containing oxide film deposited using the composition for forming a silicon-containing film of Comparative Example 1.

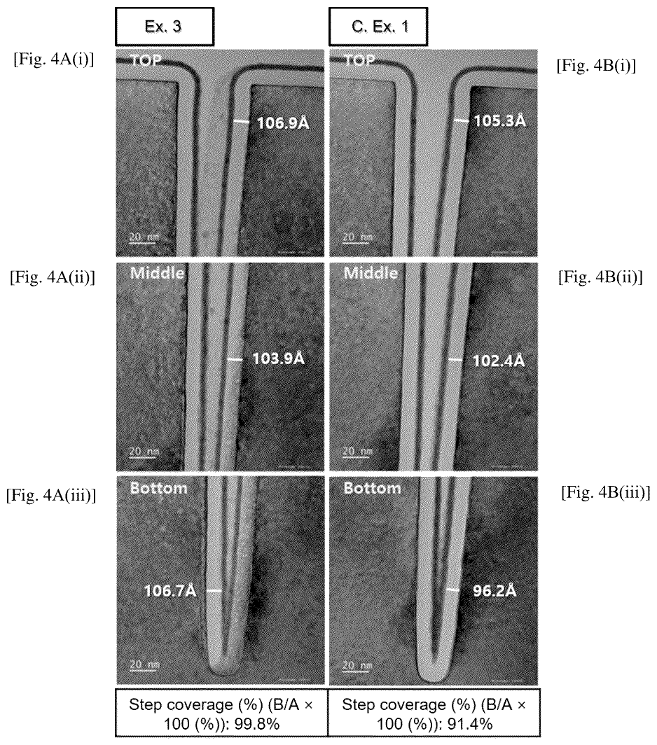

FIG. 4 is a transmission electron microscope (TEM) image of a silicon-containing oxide film formed on a wafer with a deep pattern at 650° C. by ALD using the composition for depositing a silicon-containing film of each of Example 3 and Comparative Example 1 of the present invention and ozone (O₃). Table 5 shows the thickness of the silicon-containing oxide film measured in the part shown in FIG. 4.

TABLE 5

| | Ex. 3 | C. Ex. 1 |
|---|---|---|
| Compound | Formula 1-8 | 3DMAS |
| Thickness (?) measured at the | 106.9 | 105.3 |
| top of the groove (A) | | |
| Thickness (?) measured in the | 103.9 | 102.4 |
| middle of the groove | | |
| Thickness (?) measured at the | 106.7 | 96.2 |
| bottom of the groove (B) | | |
| Step coverage (%) (B/A × 100 (%)) | 99.8% | 91.4% |

As can be seen from Table 5 above, when the composition for forming a silicon-containing film of each of Example 3 and Comparative Example 1 was deposited on a substrate having a step and then analyzed using TEM, the step coverage of the silicon-containing oxide film deposited using the composition for forming a silicon-containing film of Example 3 was 99.8%, whereas the step coverage of the silicon-containing oxide film deposited using the composition for forming a silicon-containing film of Comparative Example 1 was 91.4%. The silicon-containing oxide film deposited using the composition for forming a silicon-containing film of Example 3 had a remarkably excellent step coverage as compared with the silicon-containing oxide film deposited using the composition for forming a silicon-containing film of Comparative Example 1.

Silicon-containing oxide films formed at a temperature of 600° C. or higher using a composition comprising silicon compounds of Formula 1, other than the silicon compounds of Formulas 1-1 and 1-8, are expected to be superior to the silicon-containing oxide film formed using the composition of Comparative Example 1 in terms of the shrinkage, wet etch rate, carbon content of the film, and step coverage.

In sum, according to the method for forming a silicon-containing film using the composition for forming a silicon-containing film comprising the silicon precursor compound according to an embodiment of the present invention, it was possible to readily deposit a silicon-containing film by ALD, to precisely control the film thickness and composition, and to form a uniform film with excellent coverage even on a substrate having a complex shape.

In particular, according to the method for forming a silicon-containing film using the composition for forming a silicon-containing film comprising the silicon precursor compound according to the present invention, it is possible to obtain a film of a desired thickness at a high temperature of 600° C. to 850° C. during deposition. The silicon-containing oxide film thus obtained had significantly improved physical properties, such as step coverage, shrinkage, and wet etch rate, as compared with the silicon-containing oxide film using the composition for forming a silicon-containing film comprising the silicon precursor compound of Comparative Example 1.

1. A method for forming a silicon-containing film, which comprises depositing a silicon-containing film at 600° C. or higher using a composition for forming a silicon-containing film comprising a silicon precursor compound represented by the following Formula 1; and supplying the silicon precursor compound into a reaction chamber using at least one method selected from the group consisting of a bubbling method, a liquid delivery system (LDS) method, a vapor flow control (VFC) method, and a bypass method; wherein the step of supplying the silicon precursor compound into the reaction chamber is carried out using a transport gas or a diluent gas in a temperature range of room temperature to 150° C. and 0.1 Torr to 10 Torr, and wherein the transport gas or the diluent gas uses at least one gas selected from the group consisting of argon (Ar), nitrogen (N₂), helium (He), and hydrogen (H₂): 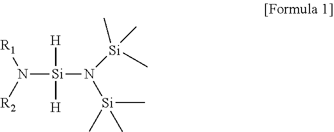
in Formula 1, R₁ and R₂ are each independently selected from the group consisting of hydrogen and a linear or branched C₁-C₄ alkyl group, or R₁ and R₂ are directly or indirectly connected to each other to form a substituted or unsubstituted C₄-C₉ cyclic group, wherein the C₄-C₉ cyclic group comprises one or two nitrogen (N) atoms and zero to two oxygen (O) atoms.

2. The method for forming a silicon-containing film of claim 1, wherein the silicon precursor compound comprises at least one selected from the group consisting of compounds represented by the following Formulae:

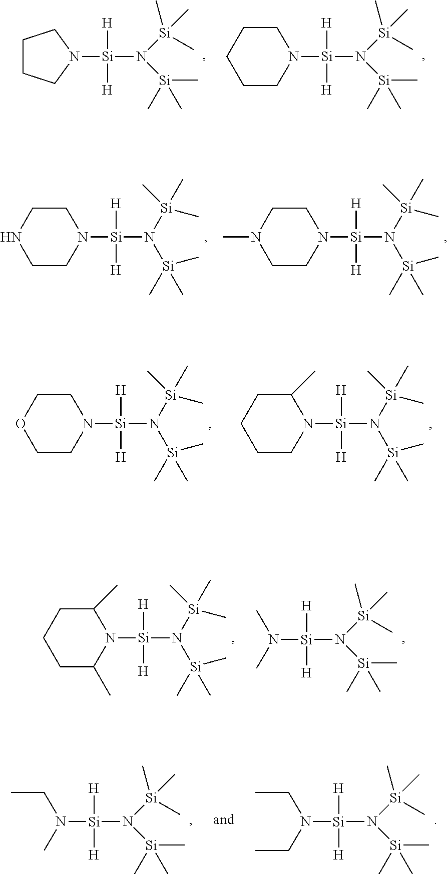

3. The method for forming a silicon-containing film of claim 1, wherein the silicon-containing film is formed at a temperature of 600° C. to 850° C. by chemical vapor deposition (CVD) or atomic layer deposition (ALD).

4. The method for forming a silicon-containing film of claim 1, wherein when a SiO₂ film is formed by an atomic layer deposition (ALD) method using the composition for forming a silicon-containing film, the growth per cycle of ALD gas supply is 1.5 to 4.5 Å/cycle in a temperature range of 600° C. to 850° C.

5-6. (canceled)

7. The method for forming a silicon-containing film of claim 1, wherein, during the deposition, thermal energy or plasma is used, or a bias is applied onto the substrate.

8. The method for forming a silicon-containing film of claim 1, wherein the silicon-containing film comprises at least one selected from the group consisting of a silicon-containing oxide film and a silicon-containing composite metal oxide film, and
at least one selected from the group consisting of water vapor (H₂O), oxygen (O₂), oxygen plasma (O₂ plasma), hydrogen peroxide (H₂O₂), and ozone (O₃) is used during the deposition.

9. The method for forming a silicon-containing film of claim 1, wherein the silicon-containing film is formed in a thickness range of 1 nm to 500 nm.

10. The method for forming a silicon-containing film of claim 1, wherein the silicon-containing film is formed on a substrate having at least one irregularity having an aspect ratio of 1 or more and a width of 1 μm or less.

11. A composition for forming a silicon-containing film, which comprises a silicon precursor compound represented by the following Formula 1 and is used in the deposition of a silicon-containing film: 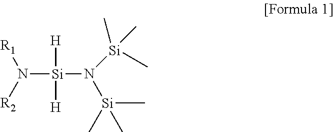
in Formula 1, R₁ and R₂ are each independently selected from the group consisting of hydrogen and a linear or branched C₁-C₄ alkyl group, or R₁ and R₂ are directly or indirectly connected to each other to form a substituted or unsubstituted C₄-C₉ cyclic group, wherein the C₄-C₉ cyclic group comprises one or two nitrogen (N) atoms and zero to two oxygen (O) atoms.

12. The composition for forming a silicon-containing film of claim 11, wherein the silicon precursor compound comprises at least one selected from the group consisting of compounds represented by the following Formulae:

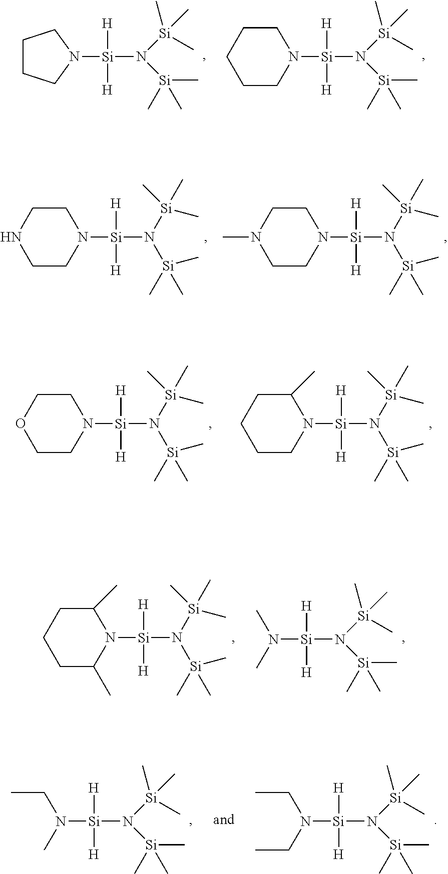

13. A silicon precursor compound represented by the following Formula 0:

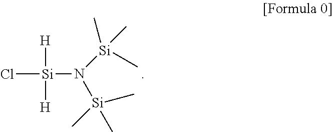

14. A silicon precursor compound represented by the following Formula 1: 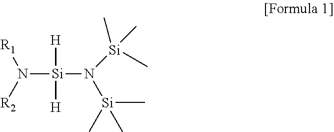
in Formula 1, R₁ and R₂ are each independently selected from the group consisting of hydrogen and a linear or branched C₁-C₄ alkyl group, or R₁ and R₂ are directly or indirectly connected to each other to form a substituted or unsubstituted C₄-C₉ cyclic group, wherein the C₄-C₉ cyclic group comprises one or two nitrogen (N) atoms and zero to two oxygen (O) atoms.

15. The compound of claim 14, wherein the silicon precursor compound comprises at least one selected from the group consisting of compounds represented by the following Formulae:

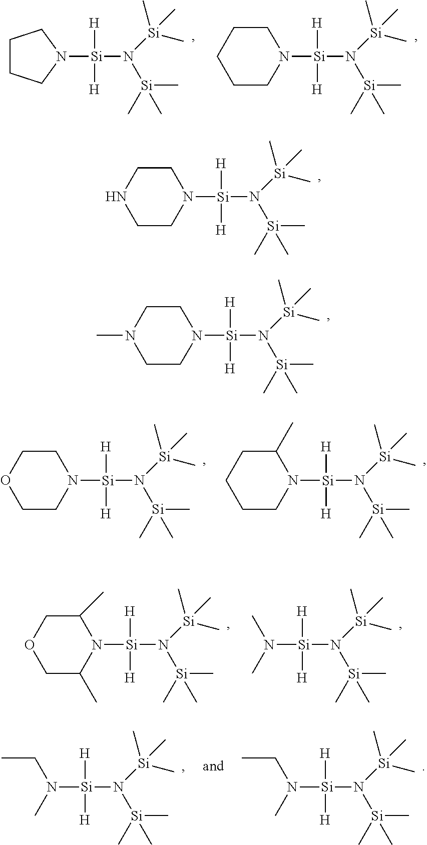

16-25. (canceled)
